(19) United States
(12) Patent Application Publication
(10) Pub. No.: US 2011/0186105 A1
(43) Pub. Date: Aug. 4, 2011

(54) SOLAR CELL ASSEMBLY WITH SOLDER LUG

(75) Inventors: Norbert PUETZ, Ottawa (CA); Simon FAFARD, Ottawa (formerly Orleans) (CA); Louis B. ALLARD, Ottawa (CA)

(73) Assignee: CYRIUM TECHNOLOGIES INCORPORATED, Ottawa (CA)

(21) Appl. No.: 13/025,696

(22) Filed: Feb. 11, 2011

Related U.S. Application Data
(60) Provisional application No. 61/304,007, filed on Feb. 12, 2010.

(51) Int. Cl. H01L 31/042

(52) U.S. Cl. 136/244

(57) ABSTRACT

A solar cell assembly with a carrier having formed thereon solder lugs. The solder lugs have a base portion that electrically connects to an electrical contact of a solar cell. The soldering lug defines a wire-receiving opening in which a heavy gauge electrical wire can be soldered or secured with electrically conductive epoxy.

### CROSS REFERENCE TO RELATED APPLICATIONS

This application claims the benefit of priority of U.S. Provisional Patent Application No. 61/304,007, filed Feb. 12, 2010, the contents of which is incorporated herein by reference in its entirety.

### TECHNICAL FIELD

The present disclosure relates generally to solar cell assemblies. More particularly, the present disclosure relates to solar cell assemblies with solder lugs.

### BACKGROUND

As is known in the art, electrical voltage and current sources, hereinafter referred to as voltage/current sources, connect to electrical loads through electrical connectors, which can include electrical wires connected at one end to the voltage/current source and at the other end to the electrical load. The electrical wires can be secured to the voltage/current source and to the load through, amongst others, solder, crimp lugs, and soldering lugs (also known as solder lugs).

Recent advances in concentrated photovoltaics (CPV) systems have seen solar cells increase in conversion efficiency while decreasing in size. A solar cell is typically mounted on a small-size carrier to form a solar cell receiver assembly, which can be integrated with concentrator optics to form a CPV module. The dimensions of such solar cells can range in size from, for example, a few square millimeters to many square centimeters. The necessity to minimize cost requires the carrier, which can be referred to as substrate, to be small in size. Currents generated by state of the art CPV solar cells, which are voltage/current sources, can be in excess of 10 A at solar concentration factors of 500 Suns or more, for solar cells having surface areas measuring 10×10 mm². Solar cells such as these require large gauge wires to connect the solar cells to a load. The wire gauge can range from, for example, AWG 14 to AWG 10 or larger, to minimize the series resistance, which substantially reduces a decrease in performance that would be caused by too high a resistance.

The wires can be soldered directly on the carrier board but in order to do this accurately and quickly, precise craftsmanship and dedicated instruments are typically required. As such, this approach might not be the most suitable for volume manufacturing. Furthermore, attaching an electrical wire directly to the carrier can be made with the length of the electrical wire being parallel to the carrier. In this configuration, it becomes difficult, if not impossible, to apply an electrical insulator material (e.g., a viscous, conformal electrical insulator material such as silicone or an electrically insulating epoxy) such as to completely surround (encapsulate) the electrical joint formed by the electrical wire and the carrier in order for the electrical insulator material to prevent electrical discharges between any bare section of the electrical wire and the ground or other part of the solar module. That is, with the soldered electrical wire soldered parallel to the carrier, it can be difficult to apply electrical insulator material on all the exposed metal regions and between the electrical wire and the carrier simply because there is little or no space to properly apply the electrical insulator material. An alternative approach that would allow improved application of viscous electrical insulator material would be to solder the wire perpendicular to the carrier by soldering the tip of the electrical wire to the carrier and subsequently bending the soldered electrical wire. Bending the soldered electrical wire at any desirable angle allows access to the electrical joint formed between the electrical wire and the carrier. However, in order to do this accurately and quickly with large diameter wire while minimizing the stress caused by bending such an electrical wire would require precise craftsmanship and dedicated instruments are required.

Another option is to connect the wires to the carrier through crimp lugs electrically connected to the carrier board. However, as carrier/cell assemblies are typically meant to operate at least 20 years without failing, crimp lugs cannot be considered as a viable options due to continuous variations in thermal stress. There are solder lugs available; however, they are not suited to be mounted on small carrier boards and to receive large gauge wires.

Therefore, improvements in solar cell assemblies and solder lugs are desirable.

### SUMMARY OF THE DISCLOSURE

In a first aspect, the present disclosure provides a solar cell assembly. The solar cell assembly comprises a carrier; a solar cell secured to carrier; a solder lug having a base, the base being surface-mounted to the carrier, the solder lug being electrically connected to the solar cell; and an electrical wire. The electrical wire has an end portion and an adjoining portion. The adjoining portion is contiguous with the end portion. The solder lug defines a wire-receiving opening into which the end portion is disposed and from which the adjoining portion extends. The opening has a perimeter portion. The perimeter portion and the base are spaced-apart by a separation distance. The separation distance allows the placement of a viscous electrical insulator material between the electrical wire and the carrier to prevent an electrical discharge between the electrical wire and the carrier.

The solder lug can have a first surface opposite the base, the first surface having an opening defined therein, the opening of the first surface to receive an electrically conductive material, the electrically conductive material to fixedly secure and to electrically connect the end portion of the electrical wire to the solder lug. The solder lug can have a second surface formed between the base and the first surface, the second surface having an opening defined therein, the opening of the second surface to receive the electrically conductive material.

The solder lug can have a first sidewall connected to the base and extending therefrom; a second sidewall connected to the base and extending therefrom; a channel structure connected to the first sidewall; and a cover structure connected to the second sidewall, the channel structure and the cover structure defining the wire-receiving opening into which the end portion of the electrical wire is disposed, the end portion being fixedly secured and electrically connected to the channel structure and to the cover structure. The wire-receiving opening can have a cross-sectional geometry that substantially corresponds to a cross-sectional geometry of the end portion of the electrical wire. The cross-sectional geometry can be circular. The base and the channel structure can define a void therebetween, the void to receive some of the viscous electrical insulator. At least one of the channel structure and the cover structure can be resilient.

The solder lug can include a solid block of electrically conductive material into which the wire-receiving opening is defined.

The solder lug can be made of a metal or of a metal alloy. The metal or the metal alloy can be coated with at least one of gold and nickel.

The solder lug can be a folded, patterned stamped metal blank.

The viscous electrical insulator material can include at least one of silicone and an insulating epoxy.

The electrically conductive material can include at least one of a solder and a conductive epoxy.

The solar cell and the solder lug can be disposed on a same side of the carrier.

The solar cell and the solder lug can be disposed on opposite sides the carrier.

In a second aspect, the present disclosure provides a solar cell assembly, which comprises a carrier; a solar cell secured to carrier; a solder lug having a base, the base being surface-mounted to the carrier, the solder lug being electrically connected to the solar cell; an electrical wire having an end portion and an adjoining portion, the adjoining portion being contiguous with the end portion, the solder lug defining a wire-receiving opening into which the end portion is disposed and from which the adjoining portion extends, the opening having a perimeter portion, the perimeter portion and the base being spaced-apart; and a cured viscous electrical insulator material formed between the electrical wire and the carrier to prevent an electrical discharge between the electrical wire and the carrier.

The solder lug can have a first sidewall connected to the base and extending therefrom; a second sidewall connected to the base and extending therefrom; a channel structure connected to the first sidewall; and a cover structure connected to the second sidewall, the channel structure and the cover structure defining the wire-receiving opening into which the end portion of the electrical wire is disposed, the end portion being fixedly secured and electrically connected to the channel structure and to the cover structure.

The solder lug can have a first surface opposite the base, the first surface having an opening defined therein, the opening of the first surface to receive an electrically conductive material, the electrically conductive material to fixedly secure and to electrically connect the end portion of the electrical wire to the solder lug.

The solder lug can have a second surface formed between the base and the first surface, the second surface having an opening defined therein, the opening of the second surface to receive the electrically conductive material.

Other aspects and features of the present disclosure will become apparent to those ordinarily skilled in the art upon review of the following description of specific embodiments of the disclosure in conjunction with the accompanying figures.

### BRIEF DESCRIPTION OF THE DRAWINGS

Embodiments of the present disclosure will now be described, by way of example only, with reference to the attached Figures.

FIG. 1 shows a top view of a solar cell assembly that comprises exemplary soldering lugs of the present disclosure.

FIG. 2 shows a top view of a soldering lug of FIG. 1.

FIG. 3 shows a first cross-sectional view of a soldering lug of FIG. 1.

FIG. 4 shows a second cross-sectional view of a soldering lug of FIG. 1.

FIG. 5 shows the cross-sectional view of FIG. 3 with an electrical wire.

FIG. 6 shows a top view of another embodiment of the soldering lug of the present disclosure.

FIG. 7 shows a partial side view of a solar cell assembly of the present disclosure.

FIG. 8 shows a front view of another embodiment of the soldering lug of the present disclosure.

### DETAILED DESCRIPTION

Generally, the present disclosure provides a solar cell assembly with solder lugs. The soldering lug has a base portion that is surface-mounted and electrically connected to a carrier on which a solar cell is secured. Each solder lug defines a wire-receiving opening in which a heavy gauge electrical wire can be soldered or secured with electrically conductive epoxy.

FIG. 1 shows an example of a solar cell 100 mounted on a carrier 102, to form an exemplary solar cell assembly 103 of the present disclosure. The top contact (not shown) of the solar cell 100 is connected to a conductive pad 104 through a series of conductors 110. The bottom contact (not shown) of the solar cell is connected to a conductive pad 106 through, for example, conductive epoxy. A bypass diode 108 interconnects the conductive pads 104 and 106. Mounted on each of the conductive pads 106 and 104 is an embodiment of a solder lug 112. An electrical wire 90 is shown positioned (received) in each solder lug 112. The electrical wires 90 can be referred to generally as electrical conductors. The electrical wires 90 can be of any suitable gauge. Each electrical wire 90 has an end portion 92 positioned (received) in a wire-receiving opening of the solder lug 112, and an adjoining portion 94 extending away from the solder lug 112. The adjoining portion 94 is contiguous with the end portion 92. The electrical wires 90 are for connecting to a load (not shown). An exemplary wire-receiving opening is disclosed below.

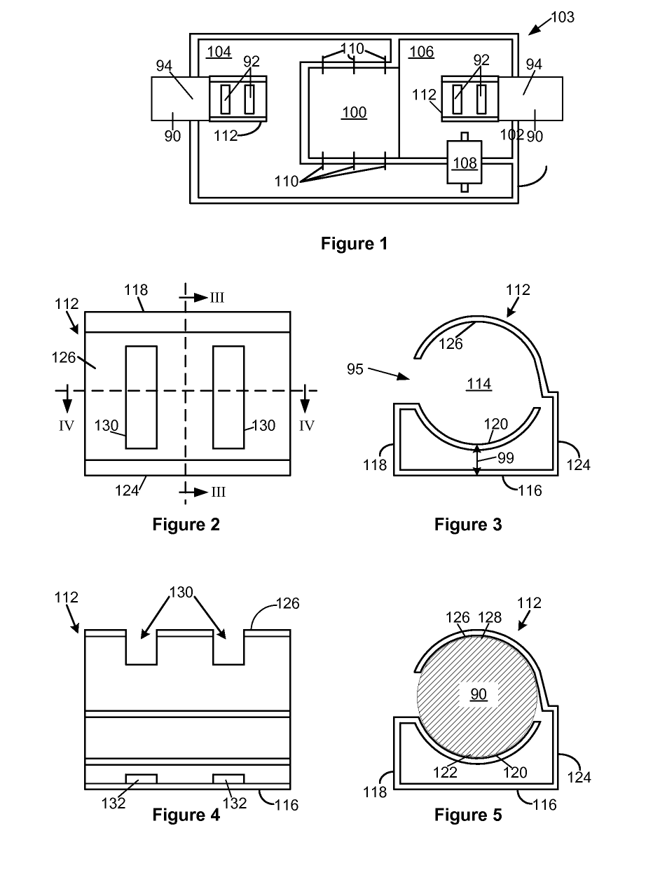

FIG. 2 shows a top view of the solder lug 112 without any electrical wire. FIGS. 3 and 4 are, respectively, cross-sectional views of the solder lug 112 taken along lines III-III and IV-IV shown in FIG. 2.

The exemplary solder lug 112 can be made by stamping a pattern in a metal sheet to obtain a patterned, stamped metal blank, and then folding the stamped metal blank into the soldering lug 112 shown in FIGS. 2-4. Any suitable metal or metal alloy can be used such as, for example, copper. The metal can be plated with gold, nickel/gold, or with any other suitable material that is impervious to oxidization and that has suitable adhesion, electrical conductivity, malleability, and thermal expansion properties. Further, intermediate materials can be disposed on the soldering lug 112 to improve the adherence of the gold or nickel/gold during plating of the solder lug 112. Such intermediate materials include, for example, tungsten, nickel, etc.

As shown in FIG. 3, the solder lug 112 defines a wire-receiving opening 114 in which an electrical wire (e.g., the electrical wire 90 shown in FIG. 1) can be inserted to be soldered and electrically connected to the solder lug 112. FIG. 5 shows the electrical wire 90 inserted in the wire-receiving opening 114. The diameter of the wire-receiving opening 114 can be designed to receive a wire snuggly but without the presence of the wire 90 in the wire-receiving opening 114 producing any substantial mechanical stress on the solder lug 112. As the soldering lug 112 can be made of flexible and resilient material (e.g. copper), the wire-receiving opening 114 can accommodate wires slightly larger than the diameter of the wire-receiving opening 114.

The solder lug 112 includes a base 116, which can be surface mounted to the carrier 102 through any suitable means, as will we disclosed below. Extending from the base 116 is a first wall 118 that connects the base 116 to a concave portion 120 of the solder lug 112. The electrical wire 90 inserted in the wire-receiving opening 114 will have a bottom wire portion 122 proximate the concave portion 120. Upon application of solder the bottom wire portion will become soldered to the concave portion 120. The trough shape of the concave portion 120 is such that substantially all of the bottom wire portion 122 inserted in the wire-receiving opening 114 will bathe in molten solder present in the concave portion 120. As the solder hardens, substantially all of the concave portion 120 will be physically connected to the bottom wire portion 122. As such, the soldering of the wire to the concave portion 120 will not give rise to appreciable electrical resistance. For concentrated photovoltaic applications, it is often desirable to keep the series resistance to less than 1 milliohm in order to minimize power losses from parasitic series resistance. The configuration of the solar cell assembly of the present disclosure can allow for such low resistance.

Also extending from the base 116 is a second wall 124 that connects the base 116 to a convex portion 126 of the solder lug 112. The electrical wire 90 inserted in the wire-receiving opening 114 will have a top wire portion 128 proximate the convex portion 126. As solder is applied, substantially all the space between the convex portion 126 and the top wire portion 128 will fill with molten solder. Upon hardening of the solder, substantially all the convex portion 126 will be connected to the top wire portion 128. As such, the soldering of the wire 90 to the convex portion 126 will not give rise to appreciable electrical resistance. The first wall 118 and the second wall 118 and 124 can be referred to as sidewalls. The concave portion 120 can be referred to as a channel portion or channel structure. The convex portion 126 can be referred to as a cover portion or cover structure. The channel structure (concave portion) and the cover structure (convex portion) define the wire-receiving opening 114. With the cover structure overlying the channel structure, and with the apparent side opening 95 shown in FIG. 3, the solder lug 112 can be referred to as a clam shell solder lug.

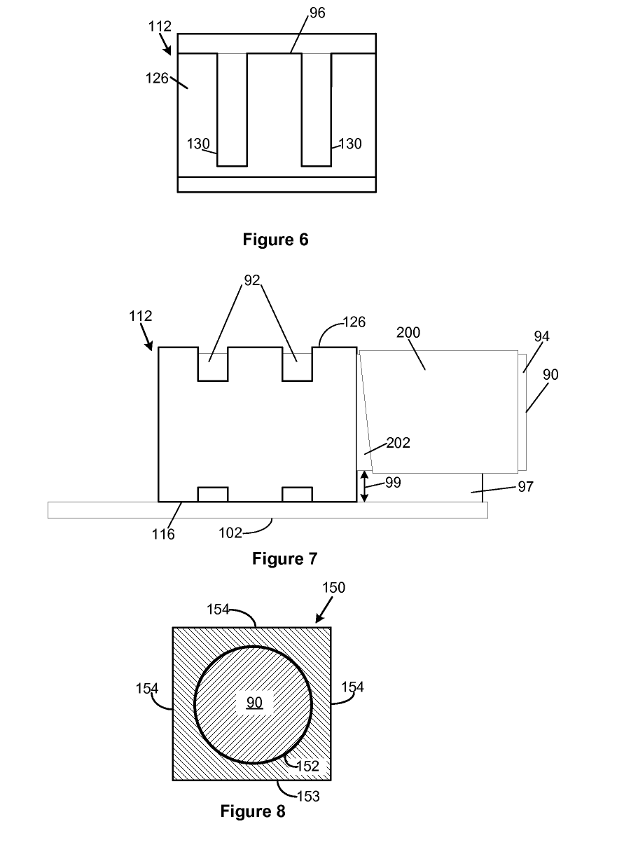

With reference to FIG. 2, it shows that the convex portion 126, which is opposite the base 116, defines openings 130 (holes) through which solder can be applied and flow to reach the top and bottom wire portions 126 and 120. The openings 130 are to receive the solder that is to connect the wire 90 to the solder lug 112. Although two openings 130 are shown, there can be any number of openings without departing from the scope of the present disclosure. Further, although the openings 130 are shown as rectangular openings, they can be of any suitable shape (e.g., circular, square, etc.) without departing from the scope of the present disclosure. Further yet, although the openings 130 are shown as being closed, the openings 130 can be opened to define a comb structure 96 such as shown in the exemplary embodiment of FIG. 6, without departing from the scope of the present disclosure. In the present embodiment of the solder lug 112, the convex portion 126 can be referred to as a surface opposite the base 116.

As an alternative to soldering, conductive epoxies or other suitable liquid conductive adhesives can be used without departing from the scope of the present disclosure. Further, even though the wire-receiving opening is shown as having a circular cross-section, any other suitably shaped wire-receiving opening (e.g., square-shaped opening, etc.) is also within the scope of the present disclosure. Any geometry of the wire-receiving receiving opening that corresponds to the geometry of the wire can be used. The solder lug of the present disclosure can be used to solder multi-strand wires or solid core wires.

The base 116 of the soldering lug 112 can be surface-mounted (e.g., fixedly secured) to the carrier 103 by way of the conductive pads (104, 106) through any suitable securing means such as conductive epoxy, solder, etc. FIG. 4 shows openings 132 that can be stamped in the aforementioned sheet metal blank. The opening 132 can be formed partly on the sidewalls (118, 124) and on the base 116, as in the present example. The openings 132 are to facilitate the flow of the securing means (e.g., solder, conductive epoxy, etc.) between the base 116 and the conductive pads (104, 106). Such openings can facilitate the removal of any gas bubbles that may be present in the securing means. Any suitable number of openings 132 in the base 116 can be used without departing from the scope of the present disclosure and, the openings can be of any suitable shape without departing from the scope of the present disclosure.

The openings 132 are located at the juncture between the base 116 and the wall 124. The openings can also be defined exclusively in the base 116, at any location in the base 116, without departing from the scope of the present disclosure.

With reference to FIGS. 3 and 7, the soldering lug 112 can be designed with any suitable spacing 99 between the base 116 and the concave portion (channel structure) 120, the concave portion 120 being a perimeter (edge, boundary, border, periphery) portion of the wire-receiving opening 114. As shown in FIG. 7, the spacing 99 allows for the placement of an electrical insulator material 97 between the carrier 102 and the electrical wire 90. Further, the electrical insulator material can be used any exposed electrical surface anywhere on the solar cell assembly 103. The electrical insulator material can be a viscous electrical insulator material such as, for example, silicone or an insulating epoxy. The electrical insulator material 97 can be applied in viscous form and subsequently cured or hardened at any suitable temperature (e.g., room temperature). The electrical wire 90 can have an insulator sheath 200 formed on its portion 94 and the end portion 92 can be bare. Upon the electrical wire 90 being positioned in the solder lug 112, it is possible, due to manufacturing and assembly variations, that a bare section 202 of the end section 92 will be outside the solder lug 112, overhanging the carrier 112. The present of an electrical insulator material 97 helps prevent electrical discharges between any bare section of the electrical wire 90 and the carrier 102. Even though the electrical wire 90 is shown as being straight, it can be bent in any direction, either before or after the end portion 92 is fixedly secured and electrically connected to the solder lug 112. Additionally, even though the solder lugs 112 are shown secured to the carrier on the same side of the carrier as the solar cell 100 (see FIG. 1), they can alternatively be secured to the opposite side of the carrier without departing from the scope of the present disclosure. This may be advantageous in certain solar modules where concentrator optics or other module components impact the available space on the solar cell side of the carrier. In such a configuration, any suitable electrical connection of the solder lugs 112 to the conductive pads 104 and 106 can be used. As an example, the carrier could have, for each solder lug, an aperture defined therein and the solder lug could have an electrically conductive tab extending from the base. The electrically conductive tab can be fitted through the aperture and electrically connected to a conductive pad. The solder lug would be surface mounted to the carrier on the carrier side opposite the side on which the solar cell is mounted.

Additionally, electrical insulator material 97 can be disposed all over the solder lug 112 to encapsulate the solder lug 112 in order to prevent moisture from reaching the solder lug 112, thereby preventing corrosion and also preventing electrical discharges between the solder lugs 112 and other electrical components in their surroundings.

By adjusting the spacing distance 99, it is possible to adapt the solder lug 112 to any solar cell module design.

Another embodiment of a solder lug of the present disclosure is shown in FIG. 8. The soldering lug 150 of FIG. 8 is made of an electrically conductive bulk material such as, for example copper. That is, the solder lug 150 is made out of a solid block of electrically conductive material. An electrical wire 90 is shown, disposed in the wire-receiving opening 152. The soldering lug 150 has a base 153, walls 154, and a wire receiving opening 152 formed therein. The soldering lug 150 can have apertures (openings) formed in the walls 154 to provide access to the electrical wire 90 from the outside of the soldering lug 150. Such apertures can improve flow of solder, or other conductive securing means, to the wire 90. The soldering lug 150 can be secured to the conductive pads (104, 106) at its base 152, similarly to the soldering lug 112.

An example of width x length x height dimensions of the solder lug of the present disclosure is 5 mm×6 mm×5.5 mm. Any other dimensions suitable for securing an electrical wire to a carrier/cell assembly are also within the scope of the present disclosure.

The solar cell assembly 103 of the present disclosure is compact and suitable for concentrated photovoltaic (CPV) solar modules. The solder lug comprised in the solar cell assembly is compact and provides a low resistance, which is required to maintained high-efficiency in CPV modules. The solder lug and its low resistance characteristics avoid fill-factor reductions and power losses due to parasitic resistances in the milliohm range or greater.

In the preceding description, for purposes of explanation, numerous details are set forth in order to provide a thorough understanding of the embodiments of the disclosure. However, it will be apparent to one skilled in the art that these specific details are not required in order to practice the disclosure. In other instances, well-known electrical structures and circuits are shown in block diagram form in order not to obscure the disclosure. For example, specific details are not provided as to whether the embodiments of the disclosure described herein are implemented as a software routine, hardware circuit, firmware, or a combination thereof.

The above-described embodiments of the disclosure are intended to be examples only. Alterations, modifications and variations can be effected to the particular embodiments by those of skill in the art without departing from the scope of the disclosure, which is defined solely by the claims appended hereto.

What is claimed is:

1. A solar cell assembly comprising:
a carrier;
a solar cell secured to carrier;
a solder lug having a base, the base being surface-mounted to the carrier, the solder lug being electrically connected to the solar cell; an
an electrical wire having an end portion and an adjoining portion, the adjoining portion being contiguous with the end portion, the solder lug defining a wire-receiving opening into which the end portion is disposed and from which the adjoining portion extends, the opening having a perimeter portion, the perimeter portion and the base being spaced-apart by a separation distance, the separation distance to allow the placement of a viscous electrical insulator material between the electrical wire and the carrier to prevent an electrical discharge between the electrical wire and the carrier.

2. The solar cell assembly of claim 1 wherein the solder lug has a first surface opposite the base, the first surface having an opening defined therein, the opening of the first surface to receive an electrically conductive material, the electrically conductive material to fixedly secure and to electrically connect the end portion of the electrical wire to the solder lug.

3. The solar cell assembly of claim 2 wherein the solder lug has a second surface formed between the base and the first surface, the second surface having an opening defined therein, the opening of the second surface to receive the electrically conductive material.

4. The solar cell assembly of claim 1 wherein the solder lug has:
a first sidewall connected to the base and extending therefrom;
a second sidewall connected to the base and extending therefrom;
a channel structure connected to the first sidewall; and
a cover structure connected to the second sidewall, the channel structure and the cover structure defining the wire-receiving opening into which the end portion of the electrical wire is disposed, the end portion being fixedly secured and electrically connected to the channel structure and to the cover structure.

5. The solar cell assembly of claim 4 wherein the wire-receiving opening has a cross-sectional geometry that corresponds to a cross-sectional geometry of the end portion of the electrical wire.

6. The solar cell assembly of claim 5 wherein the cross-sectional geometry is circular.

7. The solar cell assembly of claim 4 wherein the base and the channel structure define a void therebetween, the void to receive some of the viscous electrical insulator.

8. The solar cell assembly of claim 4 wherein at least one of the channel structure and the cover structure is resilient.

9. The solar cell assembly of claim 1 wherein the solder lug includes a solid block of electrically conductive material into which the wire-receiving opening is defined.

10. The solar cell assembly of claim 1 wherein the solder lug is made of a metal or of a metal alloy.

11. The solar cell assembly of claim 10 wherein the metal or the metal alloy is coated with at least one of gold and nickel.

12. The solar cell assembly of claim 1 wherein the solder lug is a folded, patterned stamped metal blank.

13. The solar cell assembly of claim 1 wherein the viscous electrical insulator material includes at least one of silicone and an insulating epoxy.

14. The solar cell assembly of claim 1 wherein the electrically conductive material includes at least one of a solder and a conductive epoxy.

15. The solar cell assembly of claim 1 wherein the solar cell and the solder lug are disposed on a same side of the carrier.

16. The solar cell assembly of claim 1 wherein the solar cell and the solder lug are disposed on opposite sides the carrier.

17. A solar cell assembly comprising:
a carrier;
a solar cell secured to carrier;
a solder lug having a base, the base being surface-mounted to the carrier, the solder lug being electrically connected to the solar cell;
an electrical wire having an end portion and an adjoining portion, the adjoining portion being contiguous with the end portion, the solder lug defining a wire-receiving opening into which the end portion is disposed and from which the adjoining portion extends, the opening having a perimeter portion, the perimeter portion and the base being spaced-apart; and
a cured viscous electrical insulator material formed between the electrical wire and the carrier to prevent an electrical discharge between the electrical wire and the carrier.

18. The solar cell assembly of claim 17 wherein the solder lug has:
a first sidewall connected to the base and extending therefrom;
a second sidewall connected to the base and extending therefrom;
a channel structure connected to the first sidewall; and
a cover structure connected to the second sidewall, the channel structure and the cover structure defining the wire-receiving opening into which the end portion of the electrical wire is disposed, the end portion being fixedly secured and electrically connected to the channel structure and to the cover structure.

19. The solar cell assembly of claim 17 wherein the solder lug has a first surface opposite the base, the first surface having an opening defined therein, the opening of the first surface to receive an electrically conductive material, the electrically conductive material to fixedly secure and to electrically connect the end portion of the electrical wire to the solder lug.

20. The solar cell assembly of claim 19 wherein the solder lug has a second surface formed between the base and the first surface, the second surface having an opening defined therein, the opening of the second surface to receive the electrically conductive material.
